(19) United States
(12) Patent Application Publication
(10) Pub. No.: US 2012/0097922 A1
(43) Pub. Date: Apr. 26, 2012

(54) LIGHT EMITTING ELEMENT, METHOD OF PRODUCING SAME, LAMP, ELECTRONIC EQUIPMENT, AND MECHINICAL APPARATUS

(75) Inventors: Kyosuke Masuya, Ichihara-shi (JP); Eisuke Yokoyama, Funabashi-shi (JP); Hiroshi Osawa, Chiba-shi (JP)

(73) Assignee: SHOWA DENKO K.K., Minato-ku, Tokyo (JP)

(21) Appl. No.: 13/380,429

(22) PCT Filed: Jun. 18, 2010
(86) PCT No.: PCT/JP2010/004093

§ 371 Date: Dec. 22, 2011

(30) Foreign Application Priority Data
Jun. 26, 2009 (JP) 2009-152131

(51) Int. Cl. H01L 33/06; H01L 33/32

(52) U.S. Cl. 257/13; 438/47; 257/E33.025; 257/E33.008

(57) ABSTRACT

There is provided a light-emitting element in which the driving voltage is reduced and light extraction efficiency is improved, a method of manufacturing the light-emitting element, a lamp, electronic equipment, and a mechanical apparatus. This is achieved by using a light-emitting element (1) which includes an n-type semiconductor layer (12), a light emission layer (13), a p-type semiconductor layer (14), and a titanium oxide-based conductive film layer (15), laminated in order on one face of a substrate (11), wherein a first oxide containing an element that is any one of In, Al, and Ga and a second oxide containing either Zn or Sn are present between the p-type semiconductor layer (14) and the titanium oxide-based conductive film layer (15), and the mass ratio of the second oxide to the total of the first oxide and the second oxide is in a range of 1 to 20 mass %.

### TECHNICAL FIELD

The present invention relates to a light-emitting element, a method of manufacturing the light-emitting element, a lamp, electronic equipment, and a mechanical apparatus.

Priority is claimed on Japanese Patent Application No. 2009-152131, filed Jun. 26, 2009, the contents of which are incorporated herein by reference.

### BACKGROUND ART

In recent years, a GaN-based compound semiconductor material that is a nitride-based semiconductor has drawn attention as a semiconductor material for a short-wavelength light-emitting element.

The GaN-based compound semiconductor is formed on a substrate using various oxides or III-group to V-group compounds, including a sapphire single crystal, by a metal-organic gas-phase chemical reaction method (an MOCVD method), a molecular beam epitaxy method (a MBE method), or the like.

In a case where a sapphire single crystal substrate that is an insulator is used as the structure of a general GaN-based compound semiconductor light-emitting element, an n-type semiconductor layer, a light-emitting layer, and a p-type semiconductor layer are laminated in this order and a positive electrode is also formed on the p-type semiconductor layer and a negative electrode is formed on the n-type semiconductor layer.

In the GaN-based compound semiconductor light-emitting element, there are two types, a face-up method in which a transparent electrode is used as a positive electrode and light is extracted from the p-type semiconductor side, and a flip-chip method in which a highly-reflective film such as Ag is used as a positive electrode and light is extracted from the sapphire substrate side.

As an index representing the output of a light-emitting element such as the GaN-based compound semiconductor light-emitting element, external quantum efficiency is used. If the external quantum efficiency is high, it can be said that it is a light-emitting element having a high output.

The external quantum efficiency is represented as a value obtained by multiplying internal quantum efficiency by light extraction efficiency. The internal quantum efficiency is a proportion of energy that is converted into light of the energy of an electric current injected into an element. Further, the light extraction efficiency is a proportion of light capable of being extracted to the outside of light generated in the inside of a semiconductor crystal. By improving the internal quantum efficiency and/or the light extraction efficiency, it is possible to improve the external quantum efficiency.

In order to improve the light extraction efficiency, there are two main methods. One is a method of reducing reflection loss which occurs in the interface between materials having different refractive indices, such as a compound semiconductor, an electrode, and a protective film, and the other is a method of reducing light absorption through an electrode, a protective film, or the like which is formed on a light extraction face.

As the method of reducing the reflection loss, for example, there is a method of carrying out a minute projection-recess forming work on the light extraction face side. Patent Document 1 relates to a gallium nitride-based compound semiconductor light-emitting element, and a gallium nitride-based compound semiconductor light-emitting element characterized in that a gallium nitride-based compound semiconductor layer that turns into a light-emitting element is grown on an OFF substrate of a sapphire substrate C plane (0001) and the surface of the uppermost layer of the gallium nitride-based compound semiconductor is made to be a non-mirror surface. The reflection loss which occurs in the interface between materials having different refractive indices is reduced by providing a non-mirror surface by carrying out a minute projection-recess forming work on the light extraction face side of the compound semiconductor.

However, because it is a configuration in which a minute projection-recess forming work is carried out on a compound semiconductor, damage remains in the compound semiconductor, thereby lowering internal quantum efficiency, so that it is not possible to increase luminescence intensity.

Further, as the method of reducing the light absorption, for example, there is a method of providing a transparent electrode on a p-type semiconductor. In the past, in the case of providing a transparent electrode on a p-type semiconductor of a GaN-based compound semiconductor light-emitting element, a transparent electrode made of metal such as Ni/Au has been used. However, in recent years, a transparent conductive film layer such as ITO has been put to practical use at an industrial level and has been actively used as the transparent electrode.

However, since the refractive index 1.9 of ITO is small compared to the refractive index 2.6 of a GaN-based compound semiconductor, total reflection occurs between the ITO and the GaN-based compound semiconductor, so that it is not possible to sufficiently extract light.

The refractive index of titanium oxide is 2.6 with respect to light having a wavelength of 450 nm and is approximately the same value as the refractive index of a GaN-based compound semiconductor. In recent years, therefore, turning titanium oxide that is an insulator into an electric conductor by addition of Nb or the like has been discovered (refer to Non-Patent Document 1).

Therefore, in Patent Document 2 and Patent Document 3, there are disclosed configurations in which a transparent electrode made of a titanium oxide-based conductive film is used on a p-type semiconductor layer.

For example, Patent Document 2 relates to a light-emitting element, a method of manufacturing the light-emitting element, and a lamp, and a light-emitting element in which an n-type semiconductor layer, a light-emitting layer, a p-type semiconductor layer, and a titanium oxide-based conductive film layer are laminated in this order, wherein the titanium oxide-based conductive film layer has a first layer that serves as a light extraction layer and a second layer that is disposed at the p-type semiconductor layer side of the first layer and serves as a current diffusion layer is disclosed therein.

Further, Patent Document 3 relates to a semiconductor light-emitting element, a method of manufacturing the semiconductor light-emitting element, and a lamp, and a semiconductor light-emitting element in which an n-type semiconductor layer, a light-emitting layer, a p-type semiconductor layer, and a titanium oxide-based conductive film layer are laminated in this order, wherein a projection-recess surface that is formed in at least a portion of the titanium oxide-based conductive film layer is disclosed therein.

However, even if these configurations are used, it is not possible to reduce the driving voltage of a light-emitting element and improve light extraction efficiency.

### CITATION LIST

### Patent Documents

[Patent Document 1] Japanese Patent No. 2836687

[Patent Document 2] Japanese Unexamined Patent Application Publication No. 2007-220971

[Patent Document 3] Japanese Unexamined Patent Application Publication No. 2007-220972

### Non-Patent Document:

[Non-Patent Document 1] American Institute of Physics, “A Transparent Metal: Nb-doped Anatase TiO₂”, Applied Physics Letter 86, 252101 (2005), the United States of America, Jun. 20, 2005, pp. 252101-252103

### DISCLOSURE OF INVENTION

The present invention has been made in view of the above-mentioned circumstances and has an object to provide a light-emitting element in which the driving voltage is reduced and light extraction efficiency is improved, a method of manufacturing the light-emitting element, a lamp, electronic equipment, and a mechanical apparatus,

### Solution to Problem

In order to achieve the above object, the present invention adopts the following configurations. That is,

(1) A light-emitting element including: an n-type semiconductor layer, a light-emitting layer, a p-type semiconductor layer, and a titanium oxide-based conductive film layer, which are laminated in this order on one face of a substrate, wherein a first oxide which contains an element that is any one of In, Al, and Ga and a second oxide which contains an element that is either Zn or Sn are present between the p-type semiconductor layer and the titanium oxide-based conductive film layer, and the mass ratio of the second oxide to the total of the first oxide and the second oxide is in a range of 1 mass % to 20 mass %.

(2) The light-emitting element according to the above 1, wherein the first oxide and the second oxide at least partially cover the p-type semiconductor layer.

(3) The light-emitting element according to the above 1, wherein a transparent conductive oxide layer which includes the first oxide and the second oxide is formed between the p-type semiconductor layer and the titanium oxide-based conductive film layer.

(4) The light-emitting element according to the above 3, wherein the film thickness of the transparent conductive oxide layer is 10 nm or less.

(5) The light-emitting element according to the above 3 or 4, wherein the transparent conductive oxide layer is composed of at least one or more kinds of materials which are selected from the group consisting of ITO, AZO, IZO, and GZO.

(6) The light-emitting element according to any one of the above 1 to 5, wherein the titanium oxide-based conductive film layer is made of a Ti oxide which contains at least one or more kinds of elements which are selected from the group consisting of Ta, Nb, V, Mo, W, and Sb.

(7) The light-emitting element according to any one of the above 1 to 6, wherein the film thickness of the titanium oxide-based conductive film layer is in a range of 35 nm to 2000 nm.

(8) The light-emitting element according to any one of the above 1 to 7, wherein the titanium oxide-based conductive film layer is composed of granular crystals.

(9) The light-emitting element according to any one of the above 1 to 8, wherein the n-type semiconductor layer, the light-emitting layer, and the p-type semiconductor layer are composed of nitride-based compound semiconductors.

(10) The light-emitting element according to the above 9, wherein the nitride-based compound semiconductor is a GaN-based compound semiconductor.

(11) A method of manufacturing a light-emitting element including: a process of laminating an n-type semiconductor layer, a light-emitting layer, and a p-type semiconductor layer in this order on one face of a substrate and then forming a transparent conductive oxide layer which includes a first oxide which contains an element that is any one of In, Al, and Ga and a second oxide which contains an element that is either Zn or Sn on the surface of the p-type semiconductor layer by a sputtering method; and a process of forming a titanium oxide-based conductive film layer on the transparent conductive oxide layer.

(12) The method of manufacturing a light-emitting element according to the above 11, wherein in the transparent conductive oxide layer forming process, the transparent conductive oxide layer is formed such that the first oxide and the second oxide at least partially cover the p-type semiconductor layer.

(13) The method of manufacturing a light-emitting element according to the above 11 or 12, wherein an annealing treatment is performed after the titanium oxide-based conductive film layer is formed.

(14) A lamp including the light-emitting element according to any one of the above 1 to 10.

(15) Electronic equipment including the lamp according to the above 14.

(16) A mechanical apparatus including the electronic equipment according to the above 15.

According to the above configurations, a light-emitting element of which the driving voltage is reduced and light extraction efficiency is improved, a method of manufacturing the light-emitting element, a lamp, electronic equipment, and a mechanical apparatus can be provided.

Since the light-emitting element according to the invention is configured to include the n-type semiconductor layer, the light emission layer, the p-type semiconductor layer, and the titanium oxide-based conductive film layer, which are laminated in this order on one face of the substrate, wherein the first oxide which contains an element that is any of In, Al, and Ga and the second oxide which contains an element that is either Zn or Sn are present between the p-type semiconductor layer and the titanium oxide-based conductive film layer, and the mass ratio of the second oxide to the total of the first oxide and the second oxide is in a range of 1 mass % to 20 mass %, it is possible to provide a light-emitting element in which the conductivity between the p-type semiconductor layer and the titanium oxide-based conductive film layer is improved, so that the driving voltage Vf of the light-emitting element is reduced, and also the total reflection of the light does not occur between the p-type semiconductor layer and the titanium oxide-based conductive film layer, so that light extraction efficiency is improved.

That is, an ohmic contact layer on the p-type semiconductor layer is a transparent conductive oxide layer in which a first oxide which contains an element that is any one of In, Al, and Ga and a second oxide which contains an element that is either Zn or Sn are present therein and the mass ratio of the second oxide to the total of the first and second oxides is in a range of 1 mass % to 20 mass %, and furthermore, the refractive index is 2.6 with respect to light having a wavelength of 450 nm and is approximately the same value as the refractive index of a GaN-based compound semiconductor, and therefore, light extraction efficiency can be improved.

Further, when the film thickness of the transparent conductive oxide layer which is formed between the p-type semiconductor layer and the titanium oxide-based conductive film layer is 10 nm or less, the above effects can be dramatically improved.

Since the method of manufacturing the light-emitting element according to the invention is configured to include a process of laminating the n-type semiconductor layer, the light-emitting layer, and the p-type semiconductor layer in this order on one face of the substrate and then forming the transparent conductive oxide layer which includes the first oxide which contains an element that is any one of In, Al, and Ga and the second oxide which contains an element that is either Zn or Sn on the surface of the p-type semiconductor layer by a sputtering method; and a process of forming the titanium oxide-based conductive film layer on the transparent conductive oxide layer, it is possible to manufacture a light-emitting element in which the conductivity between the p-type semiconductor layer and the titanium oxide-based conductive film layer is improved, so that the driving voltage Vf of the light-emitting element is reduced, and also the total reflection of the light does not occur between the p-type semiconductor layer and the titanium oxide-based conductive film layer, so that light extraction efficiency is improved.

Since the lamp according to the invention is configured to be provided with the light-emitting element described above, it is possible to provide a lamp in which the conductivity between the p-type semiconductor layer and the titanium oxide-based conductive film layer is improved, so that the driving voltage Vf of the light-emitting element is reduced, and also the total reflection of the light does not occur between the p-type semiconductor layer and the titanium oxide-based conductive film layer, so that light extraction efficiency is improved.

Since the electronic equipment according to the invention has a configuration in which the lamp described above is incorporated, it is possible to provide electronic equipment provided with a lamp in which the conductivity between the p-type semiconductor layer and the titanium oxide-based conductive film layer is improved, so that the driving voltage Vf of the light-emitting element is reduced, and also the total reflection of the light does not occur between the p-type semiconductor layer and the titanium oxide-based conductive film layer, so that light extraction efficiency is improved.

Since the mechanical apparatus according to the invention has a configuration in which the electronic equipment described above is incorporated, it is possible to provide a mechanical apparatus provided with a lamp in which the conductivity between the p-type semiconductor layer and the titanium oxide-based conductive film layer is improved, so that the driving voltage Vf of the light-emitting element is reduced, and also the total reflection of the light does not occur between the p-type semiconductor layer and the titanium oxide-based conductive film layer, so that light extraction efficiency is improved.

### BRIEF DESCRIPTION OF THE DRAWINGS

FIG. 1 is a diagram illustrating one example of a light-emitting element according to the invention, wherein FIG. 1(a) is a plan view and FIG. 1(b) is a cross-sectional view taken along line A-A′ in FIG. 1(a).

FIG. 2 is a flow chart illustrating one example of a method of manufacturing the light-emitting element according to the invention.

FIG. 3 is a manufacturing process diagram illustrating one example of the method of manufacturing the light-emitting element according to the invention.

FIG. 4 is a manufacturing process diagram illustrating one example of the method of manufacturing the light-emitting element according to the invention.

FIG. 5 is a manufacturing process diagram illustrating one example of the method of manufacturing the light-emitting element according to the invention.

FIG. 6 is a manufacturing process diagram illustrating one example of the method of manufacturing the light-emitting element according to the invention.

FIG. 7 is a manufacturing process diagram illustrating one example of the method of manufacturing the light-emitting element according to the invention.

FIG. 8 is a cross-sectional view illustrating one example of a lamp according to the invention.

FIG. 9 is a diagram illustrating another example of the light-emitting element according to the invention, wherein FIG. 9(a) is a plan view and FIG. 9(b) is a cross-sectional view taken along line B-B′ in FIG. 9(a).

### DESCRIPTION OF EMBODIMENTS

Hereinafter, a mode for carrying out the invention will be described. In addition, in the drawings used in the following explanation, there are cases where characteristic sections are enlarged and shown for convenience in order to facilitate the understanding of features, and the size ratio or the like of each constituent element is not necessarily the same as in practice.

### First Embodiment

### Light-Emitting Element

A light-emitting element related to a first embodiment of the invention will be described.

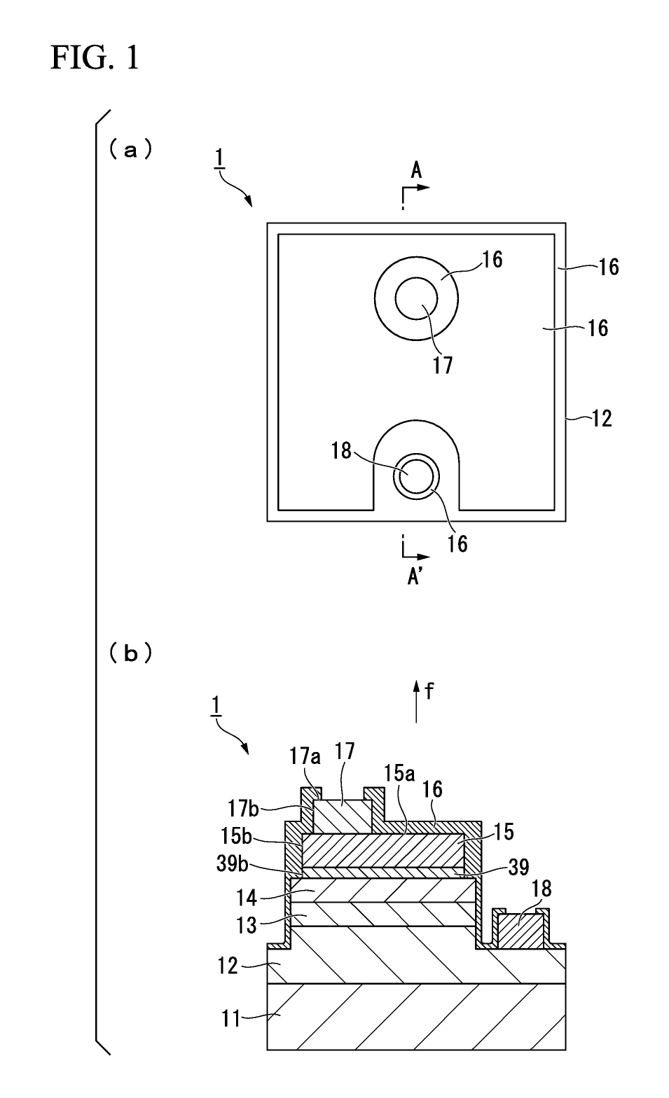

FIG. 1 is a diagram illustrating one example of the light-emitting element related to the embodiment of the invention, wherein FIG. 1(a) is a plan view and FIG. 1(b) is a cross-sectional view taken along line A-A′ in FIG. 1(a).

As shown in FIG. 1(a), a light-emitting element 1 related to the embodiment of the invention is schematically configured to include an approximately rectangular n-type semiconductor layer 12, a photocatalytic reaction prevention layer 16, a circular positive electrode 17, and a circular negative electrode 18.

Further, as shown in FIG. 1(b), the light-emitting element 1 related to the embodiment of the invention is schematically configured to include the n-type semiconductor layer 12, a light-emitting layer 13, a p-type semiconductor layer 14, a transparent conductive oxide layer 39, a titanium oxide-based conductive film 15, and the positive electrode 17, which are laminated in this order on a substrate 11. In addition, in the following explanation, the face on the opposite side to the substrate 11 of each layer is referred to as one face.

Further, the light-emitting layer 13, the p-type semiconductor layer 14, and the n-type semiconductor layer 12 are partially cut off and the negative electrode 18 is formed on one face 12a of the n-type semiconductor layer 12.

Further, the photocatalytic reaction prevention layer 16 is formed so as to cover a side surface 17b and an upper surface peripheral portion 17a of the positive electrode 17, a side surface 15b and one face 15a of the titanium oxide-based conductive film 15, the exposed surfaces of the n-type semiconductor layer 12, the light-emitting layer 13, and the p-type semiconductor layer 14, and the side surface of the negative electrode 18. In addition, the photocatalytic reaction prevention layer 16 is also referred to as a protective layer 16.

Hereinafter, each layer will be described.

Substrate

As the substrate 11, well-known substrate materials can be used such as an oxide single crystal such as a sapphire single crystal (Al₂O₃; an A plane, a C plane, an M plane, or an R plane), a spinel single crystal (MgAl₂O₄), a ZnO single crystal, an LiAlO₂ single crystal, an LiGaO₂ single crystal, or an MgO single crystal, a Si single crystal, a SiC single crystal, a GaAs single crystal, an AlN single crystal, a GaN single crystal, and a boride single crystal such as a ZrB₂. Further, any substrate material other than these well-known substrate materials can be used without any limitation. Among these well-known substrate materials, the sapphire single crystal and the SiC single crystal are particularly preferable.

In addition, the plane orientation of the substrate is not particularly limited. Further, an aligned substrate is also acceptable and a substrate with an off angle given thereto is also acceptable.

Nitride-Based Compound Semiconductor

As shown in FIG. 1(b), the n-type semiconductor layer 12, the light-emitting layer 13, and the p-type semiconductor layer 14 are laminated on the substrate 11. In addition, a buffer layer (not shown) is usually provided between the n-type semiconductor layer 12 and the substrate 11. Depending on the substrate which is used or the growth conditions of an epitaxial layer, there is also a case where the buffer layer is not required.

As the n-type semiconductor layer 12, the light-emitting layer 13, the p-type semiconductor layer 14, and the buffer layer, a nitride-based compound semiconductor can be used.

As the nitride-based compound semiconductor, for example, there is a gallium nitride-based compound semiconductor which is represented by a general formula, Al_{X}Ga_{Y}In_{Z}N_{1-A}M_{A} (0≦X≦1, 0≦Y≦1, 0≦Z≦1, and X+Y+Z=1, and symbol M expresses a V-group element different from nitrogen (N), and 0≦A≦1). In the invention, the gallium nitride-based compound semiconductor which is represented by a general formula, Al_{X}Ga_{Y}In_{Z}N_{1-A}M_{A} (0≦X≦1, 0≦Y≦1, 0≦Z≦1, and X+Y+Z=1, and symbol M expresses a V-group element different from nitrogen (N), and 0≦A<1), can be used without any limitation.

The nitride-based compound semiconductor can contain III-group elements other than Al, Ga, and In and can also contain elements such as Ge, Si, Mg, Ca, Zn, Be, P, and As as necessary.

Further, there is also a case where the nitride-based compound semiconductor contains not only the intentionally added elements, but also impurities which are inevitably contained depending on film formation conditions or the like, and minute impurities which are contained in a raw material or a reaction tube material.

In addition, the refractive index of the GaN-based compound semiconductor is 2.6.

### N-Type Semiconductor Layer

Usually, the n-type semiconductor layer 12 is composed of a base layer, an n-type contact layer, and an n-type cladding layer. The n-type contact layer can double as the base layer and/or the n-type cladding layer.

It is preferable that the base layer be constituted by an AlₓGa₁₋ₓN layer (0≦x≦1, preferably, 0≦x≦0.5, more preferably, 0≦x≦0.1). Further, with respect to the film thickness of the base layer, 0.1 μm or more is preferable, 0.5 μm or more is more preferable, and 1 μm or more is most preferable. By setting the film thickness of the base layer to be 1 μm or more, an AlₓGa₁₋ₓN layer having excellent crystallinity can be easily obtained.

It is preferable that the base layer be formed without doping (<1×10¹⁷/cm³). By forming the base layer without doping, it is possible to maintain excellent crystallinity. However, provided that it is within a range of 1×10¹⁷/cm³ to 1×10¹⁹/cm³, an n-type impurity may also be doped thereto. As the n-type impurity, although it is not particularly limited, Si, Ge, Sn, or the like can be given as an example, and Si and Ge are preferable.

It is preferable that the n-type contact layer be constituted by an AlₓGa₁₋ₓN layer (0≦x≦1, preferably, 0≦x≦0.5, more preferably, 0≦x≦0.1), similarly to the base layer.

Further, in the n-type contact layer, it is preferable that an n-type impurity be doped thereto. Further, it is preferable that the concentration of the n-type impurity be set to be in a range of 1×10¹⁷/cm³ to 1×10¹⁹/cm³, and it is more preferable that it be set in a range of 1×10¹⁸/cm³ to 1×10¹⁹/cm³. By setting the concentration of the n-type impurity to be in a range of 1×10¹⁷/cm³ to 1×10¹⁹/cm³, it is possible to maintain excellent ohmic contact with the negative electrode and also suppress occurrence of cracks, thereby maintaining excellent crystallinity.

As the n-type impurity, although it is not particularly limited, Si, Ge, Sn, or the like can be given as an example, and Si and Ge are preferable.

It is preferable that the n-type contact layer and the base layer be made of nitride-based compound semiconductors having the same composition.

Then, it is preferable that the total film thickness of the n-type contact layer and the base layer be set to be in a range of 1 μm to 20 μm, it is more preferable that it be set in a range of 2 μm to 15 μm, and it is further preferable that it be set in a range of 3 μm to 12 μm.

If the total film thickness of the n-type contact layer and the base layer is in a range of 1 μm to 20 μm, it is possible to maintain the excellent crystallinity of the nitride-based compound semiconductor.

It is preferable to provide the n-type cladding layer between the n-type contact layer and the light-emitting layer 13. By providing the n-type cladding layer, it is possible to fill up locations with less evenness generated in the top surface of the n-type contact layer.

The n-type cladding layer can be formed by AlGaN, GaN, GaInN or the like. In addition, in this specification, these materials are described as AlGaN, GaN, and GaInN with the composition ratio of each element omitted. The n-type cladding layer may also be set to have a superlattice structure in which two or more compositions which are selected from these compositions are laminated plural times.

The band gap of the n-type cladding layer is set to be larger than the band gap of the light-emitting layer 13.

With respect to the film thickness of the n-type cladding layer, although it is not particularly limited, it is preferable that it be set in a range of 0.005 μm to 0.5 μm, and it is more preferable that it be set in a range of 0.005 μm to 0.1 μm.

Further, it is preferable that the n-type doping concentration of the n-type cladding layer be set to be in a range of 1×10¹⁷/cm³ to 1×10²°/cm³, and it is more preferable that it be set in a range of 1×10¹⁸/cm³ to 1×10¹⁹/cm³. If the n-type doping concentration of the n-type cladding layer is in a range of 1×10¹⁷/cm³ to 1×10²°/cm³, it is possible to maintain excellent crystallinity and also reduce the operating voltage of the light-emitting element.

Light-Emitting Layer

As the light-emitting layer 13 which is laminated on the n-type semiconductor layer 12, a light-emitting layer made of a nitride-based compound semiconductor is usually used. As the nitride-based compound semiconductor, Ga₁₋ₛInₛN (0<s<0.4) can be given.

As the film thickness of the light-emitting layer 13, although it is not particularly limited, it is preferable that it be set to be a film thickness of the extent that a quantum effect can be obtained, that is, a critical film thickness. Specifically, it is preferable that the film thickness of the light-emitting layer 13 be set to be in a range of 1 nm to 10 nm, and it is more preferable that it be set in a range of 2 nm to 6 nm. By setting the film thickness of the light-emitting layer 13 to be in a range of 1 nm to 10 nm, it is possible to improve a luminescence output.

Further, the light-emitting layer 13 may be set to be a single quantum well (SQW) structure and may also be set to be a multiple quantum well (MQW) structure. The multiple quantum well (MQW) structure is made by laminating in a plurality, for example, a well layer made of Ga₁₋ₛInₛN (hereinafter referred to as a GaInN well layer) and a barrier layer made of Al_{c}Ga_{1-c}N (0≦c<0.3 and b>c) (hereinafter referred to as a Al_{c}Ga_{1-c}N barrier layer) having larger band gap energy than the GaInN well layer so as to be alternate. Impurities may also be doped to each of the well layer and/or the barrier layer.

As the barrier layer, a Si-doped GaN barrier layer may also be used.

P-Type Semiconductor Layer

The p-type semiconductor layer 14 is usually composed of a p-cladding layer and a p-contact layer. However, the p-contact layer may also double as the p-cladding layer.

As the p-cladding layer, provided that it is a composition in which band gap energy becomes larger than that of the light-emitting layer and that it makes carriers be confined in the light-emitting layer 13, it is not particularly limited. As the p-cladding layer, Al_{d}Ga_{1-d}N (0≦d≦0.4, preferably, 0.1≦d≦0.3) can be given as an example. By constituting the p-cladding layer by Al_{d}Ga_{1-d}N, it is possible to confine carriers in the light-emitting layer 13.

Further, with respect to the film thickness of the p-cladding layer, although it is not particularly limited, it is preferable that it be set in a range of 1 nm to 400 nm, and it is more preferable that it be set in a range of 5 nm to 100 nm. Further, with respect to the p-type doping concentration of the p-cladding layer, it is preferable that it be set in a range of 1×10¹⁸/cm³ to 1×10²¹/cm³, and it is more preferable that it be set in a range of 1×10¹⁹/cm³ to 1×10²°/cm³. By setting the p-type doping concentration of the p-cladding layer to be in a range of 1×10¹⁸/cm³ to 1×10²¹/cm³, it is possible to obtain an excellent p-type crystal without lowering crystallinity.

As the p-contact layer, a nitride-based compound semiconductor layer which contains at least AlₑGa₁₋ₑN (0≦e<0.5, preferably, 0≦e≦0.2, more preferably, 0≦e≦0.1) can be used.

By setting Al composition in AlₑGa₁₋ₑN to be in the relationship of 0≦e<0.5, it is possible to maintain excellent crystallinity and also obtain excellent ohmic contact with the p-type ohmic electrode. Further, with respect to the concentration of a p-type dopant of the p-contact layer, it is preferable that it be set in a range of 1×10¹⁸/cm³ to 1×10²¹/cm³, and it is more preferable that it be set in a range of 5×10¹⁹/cm³ to 5×10²⁰/cm³. By setting the concentration of a p-type dopant of the p-contact layer to be in a range of 1×10¹⁸/cm³ to 1×10²¹/cm³, it is possible to maintain excellent ohmic contact and prevent occurrence of cracks, thereby maintaining excellent crystallinity.

Further, as the p-type dopant (a p-type impurity), although not particularly limited, Mg can be given as an example. Further, with respect to the film thickness of the p-contact layer, although it is not particularly limited, it is preferable that it be set in a range of 0.01 μm to 0.5 μm, and it is more preferable that it be set in a range of 0.05 μm to 0.2 μm. By making the film thickness of the p-contact layer be in a range of 0.01 μm to 0.5 μm, it is possible to improve a luminescence output.

Transparent Conductive Oxide Layer

The transparent conductive oxide layer 39 having a first oxide which contains an element that is any one of In, Al, and Ga and a second oxide which contains an element that is either Zn or Sn is formed between the p-type semiconductor layer 14 and the titanium oxide-based conductive film layer 15.

That is, in the transparent conductive oxide layer 39, the first oxide which contains an element that is any one of In, Al, and Ga and the second oxide which contains an element that is either Zn or Sn are present.

With respect to the mass ratio of the second oxide to the total of the first oxide and the second oxide, it is preferable that it be set in a range of 1 mass % to 20 mass %, and it is more preferable that it be set in a range of 5 mass % to 20 mass %.

By making these elements be present in the above concentration range between the p-type semiconductor layer 14 and the titanium oxide-based conductive film layer 15, it is possible to reduce contact resistance between the p-type semiconductor layer 14 and the titanium oxide-based conductive film layer 15, thereby improving conductivity, and reduce driving voltage Vf of the light-emitting element.

Further, even if the first oxide which contains an element that is any one of In, Al, and Ga and the second oxide which contains an element that is either Zn or Sn are present between the p-type semiconductor layer 14 and the titanium oxide-based conductive film layer 15, it is possible to secure a transmittance of 80% or more in a wavelength in a range of 300 nm to 550 nm, thereby improving light extraction efficiency in a front direction f.

With respect to the film thickness of the transparent conductive oxide layer 39, it is preferable that it be set to be 10 nm or less, it is more preferable that it be set to be 8 nm or less, and it is further preferable that it be set to be 5 nm or less.

By making the transparent conductive oxide layer 39 having these oxides be present in a film thickness of 10 nm or less between the p-type semiconductor layer 14 and the titanium oxide-based conductive film layer 15, it is possible to improve the conductivity between the p-type semiconductor layer 14 and the titanium oxide-based conductive film layer 15, thereby reducing the driving voltage Vf of the light-emitting element.

Further, it is preferable that the film thickness of the transparent conductive oxide layer 39 be set to be 0.3 nm or more. In a case where it is less than 0.3 nm, because it is a thin film, it becomes difficult to obtain sufficient conductivity.

As the transparent conductive oxide layer 39, it is possible to use, for example, a film composed of one or more kinds of oxides such as In₂O₃—SnO₂ (hereinafter referred to as ITO) having refractive index of 1.9, ZnO—Al₂O₃ (hereinafter referred to as AZO) having refractive index of 2.1, In₂O₃—ZnO (hereinafter referred to as IZO) having refractive index of 1.9, and ZnO—Ga₂O₃ (hereinafter referred to as GZO) having refractive index of 2.1.

By making the transparent conductive oxide layer 39 having these elements be present in a film thickness of 10 nm or less between the p-type semiconductor layer 14 and the titanium oxide-based conductive film layer 15, it is possible to improve light extraction efficiency without making the total reflection of light occur between the p-type semiconductor layer 14 and the transparent conductive oxide layer 39. Further, it is possible to secure a transmittance of 80% or more in a wavelength in a range of 300 nm to 550 nm, thereby improving light extraction efficiency in the front direction f.

For example, in a case where the p-type semiconductor layer 14/the transparent conductive oxide layer 39/the titanium oxide-based conductive film layer 15 is made to be a GaN-based compound semiconductor (refractive index: 2.6)/ITO (refractive index: 1.9)/Ti₁₋ₓAₓO₂ (A=Ta, Nb, V, Mo, W, or Sb) (refractive index: 2.6) and the film thickness of the ITO is set to be thick, generally, the total reflection of light radiated from the light-emitting layer 13 occurs between the GaN-based compound semiconductor and the ITO, so that light extraction efficiency is lowered.

However, in this embodiment, because the film thickness of the ITO that is the transparent conductive oxide layer 39 is configured to be 10 nm or less, the total reflection of the light does not occur between the GaN-based compound semiconductor and the ITO, so that light extraction efficiency in the front direction f can be improved. Furthermore, since the film thickness of the transparent conductive oxide layer 39 is made to be 10 nm or less, it is possible to secure a transmittance of 80% or more in a wavelength in a range of 300 nm to 550 nm, thereby improving light extraction efficiency in the front direction f.

Titanium Oxide-Based Conductive Film Layer

The titanium oxide-based conductive film layer 15 is formed above the p-type semiconductor layer 14. The titanium oxide-based conductive film 15 is used as a transparent electrode. That is, the titanium oxide-based conductive film 15 is used as a light extraction layer and at the same time, is used as a current diffusion layer.

It is preferable that the titanium oxide-based conductive film layer 15 be made of an oxide which contains Ti and at least one kind of element which is selected from Ta, Nb, V, Mo, W, and Sb.

The composition of the oxide is represented by Ti_{1-X}A_{X}O₂ (A=Ta, Nb, V, Mo, W, or Sb). It is preferable that the composition X in Ti_{1-X}A_{X}O₂ be set to be in a range of 1 at % to 20 at %, and it is more preferable that it be set to be in a range of 2 at % to 10 at %. If the composition X in Ti_{1-X}AₓO₂ is less than 1 at %, the effect to add A is small, so that excellent conductivity cannot be obtained. On the contrary, if the composition X in Ti_{1-X}A_{X}O₂ exceeds 20 at %, transmittance in a wavelength in a range of 300 nm to 550 nm is lowered, so that the output of the light-emitting element is lowered.

In addition, the refractive index of Ti_{1-X}A_{X}O₂ (A=Ta, Nb, V, Mo, W, or Sb) is 2.6.

It is preferable that Ti_{1-X}A_{X}O₂ (A=Ta, Nb, V, Mo, W, or Sb) be set to be in an oxygen defect state. This is because the conductivity of Ti_{1-X}A_{X}O₂ (A=Ta, Nb, V, Mo, W, or Sb) varies in accordance with oxygen composition and if it is set to be in an oxygen defect state, the conductivity of Ti_{1-Z}A_{X}O₂ becomes high.

As a method of creating the oxygen defect state, it is possible to use a method of adjusting the amount of oxygen by reactive deposition with oxygen using metal, or reactive sputtering, a method using a metal oxide tablet or target which is in an oxygen defect state, a method of performing annealing in a reducing atmosphere such as N₂ or H₂ after the formation of the titanium oxide-based conductive film, or the like.

With respect to the film thickness of the titanium oxide-based conductive film layer 15, it is preferable that it be set in a range of 35 nm to 2000 nm, it is more preferable that it be set in a range of 50 nm to 1000 nm, and it is most preferable that it be set in a range of 100 nm to 500 nm. In a case where the film thickness of the titanium oxide-based conductive film layer 15 is less than 35 nm, current diffusion efficiency is lowered. On the contrary, in a case where the film thickness of the titanium oxide-based conductive film layer 15 exceeds 2000 nm, transmittance becomes worse, so that output is lowered.

With respect to the crystal structure of the titanium oxide-based conductive film layer 15, although it is not particularly limited, among a rutile type, an anatase type, and a brookite type (an orthorhombic crystal), it is preferable that it be set to be the anatase type which is easily created at low temperatures. By setting the crystal structure of the titanium oxide-based conductive film layer 15 to be the anatase type, it is possible to make conductivity excellent.

However, since the titanium oxide-based conductive film layer 15 has photocatalytic action (photocatalytic reactivity) and in particular, the anatase type is a crystal structure having the highest photocatalytic action, some measures to suppress photocatalytic reactivity are required. Titanium oxide decomposes water or organic substances through the photocatalytic action. Therefore, in a case where a lamp is constituted by sealing a light-emitting element having the titanium oxide-based conductive film layer 15 by organic substance such as resin, there is concern that the organic substance may be decomposed by light, thereby adversely affecting the light-emitting element.

For example, by adding iron, aluminum, magnesium, zirconium, or the like to the titanium oxide-based conductive film layer 15, it is possible to weaken the photocatalytic action of the titanium oxide-based conductive film. However, it is necessary to set the addition amount of the element to be in a range not significantly damaging to the conductivity and the permeability of the titanium oxide-based conductive film.

Further, as will be described later, by forming the photocatalytic reaction prevention layer, it is also possible to suppress the photocatalytic reaction.

Positive Electrode

The positive electrode 17 is formed on one face 15a of the titanium oxide-based conductive film layer 15. The positive electrode 17 is used as a bonding pad.

As the positive electrode 17, well-known materials such as Au, Al, Ni, and Cu and various structures using the above materials can be used without any limitation.

With respect to the thickness of the positive electrode 17, it is preferable that it be set in a range of 100 nm to 10 μm, and it is more preferable that it be set in a range of 300 nm to 3 μm. By setting the thickness of the positive electrode 17 to be 300 nm or more, it is possible to improve bondability as a bonding pad. Further, by setting the thickness of the positive electrode 17 to be 3 μm or less, it is possible to reduce manufacturing costs.

Photocatalytic Reaction Prevention Layer (Protective Film Layer)

As shown in FIG. 1(b), the photocatalytic reaction prevention layer 16 is formed so as to cover the side surface 17b and the upper surface peripheral portion 17a of the positive electrode 17, the side surface 15b and one face 15a of the titanium oxide-based conductive film layer 15, one face of the n-type semiconductor layer 12, the exposed surfaces of the light-emitting layer 13 and the p-type semiconductor layer 14, and the side surface of the negative electrode 18. By forming the photocatalytic reaction prevention layer 16 in this manner, it is possible to prevent infiltration of moisture or the like into the inside of the light-emitting element 1, thereby suppressing deterioration of the light-emitting element 1. In particular, it is possible to prevent infiltration of moisture or the like into the interface between the photocatalytic reaction prevention layer 16 and the transparent conductive oxide layer 39, thereby preventing the photocatalytic action of the titanium oxide-based conductive film layer 15.

As the photocatalytic reaction prevention layer 16, an insulating transparent film can be used.

As the insulating transparent film, it is acceptable if it is a material having insulation properties and also having transmittance of 80% or more in a wavelength in a range of 300 nm to 550 nm. For example, a silicon oxide (for example, SiO₂), an aluminum oxide (for example, Al₂O₃), a hafnium oxide (for example, HfO₂), a niobium oxide (for example, Nb₂O₅), a tantalum oxide (for example, Ta₂O₅), a silicon nitride (for example, Si₃N₄), an aluminum nitride (for example, AlN), or the like can be used. Among these, SiO₂ and Al₂O₃ are more preferable because a dense film can be easily made by CVD film-formation. Al₂O₃ is further preferable because reliability under high temperature and high humidity can be further improved by film-formation by a CVD method.

With respect to the film thickness of the photocatalytic reaction prevention layer 16, although it is not particularly limited, a range 10 nm to 10 μm is preferable. If the film thickness of the photocatalytic reaction prevention layer 16 is less than 10 nm, it is too thin, so that it is not possible to prevent infiltration of moisture or the like. Further, with respect to the upper limit of the film thickness of the photocatalytic reaction prevention layer 16, although it is not particularly limited, it is preferable that it be set to be 10 μm in terms of productivity.

In addition, another transparent film or the like may also be disposed between the titanium oxide-based conductive film 15 and the photocatalytic reaction prevention layer 16. In particular, by interposing a transparent film having refractive index of a numerical value between the refractive index 2.6 of the titanium oxide-based conductive film 15 and the refractive index of the photocatalytic reaction prevention layer 16 therebetween, it is possible to improve light extraction efficiency.

For example, in a case where SiO₂ (refractive index: 1.5) or Al₂O₃ (refractive index: 1.6) is used in the photocatalytic reaction prevention layer 16, it is preferable to interpose a transparent film having refractive index in a range of 1.6 to 2.6 therebetween.

As the transparent film, CeO₂ (refractive index: 2.2), HfO₂ (refractive index: 1.9), MgO (refractive index: 1.7), ITO (refractive index: 1.9), Nb₂O₅ (refractive index: 2.3), Ta₂O₅ (refractive index: 2.2), Y₂O₃ (refractive index: 1.9), ZnO (refractive index: 2.1), ZrO₂ (refractive index: 2.1), or the like can be given.

Negative Electrode

The negative electrode 18 is formed so as to come into contact with the n-type semiconductor layer 12 in which the n-type contact layer of the n-type semiconductor layer 12 is exposed by partially removing the n-type semiconductor layer 12, the light-emitting layer 13, and the p-type semiconductor layer 14 laminated on the substrate 11, as shown in FIG. 1. The negative electrode 18 is used as a bonding pad.

As the negative electrode 18, negative electrodes having various well-known compositions and structures can be used without any limitation, and it can be provided by commonly-used means well known in the art.

Next, a method of manufacturing the light-emitting element related to the embodiment of the invention will be described.

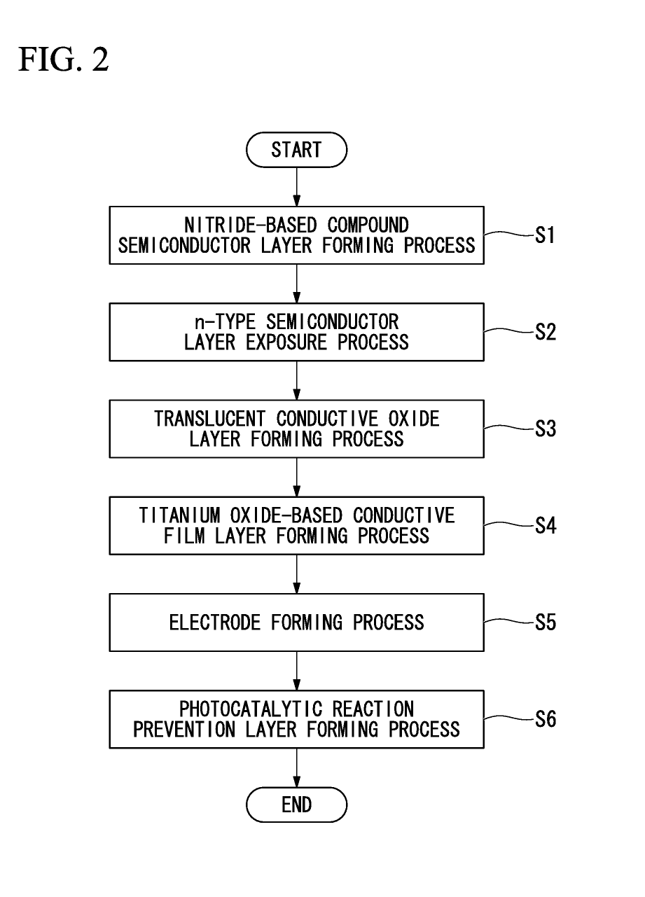

FIG. 2 is a flow chart illustrating one example of the method of manufacturing the light-emitting element related to the embodiment of the invention.

As shown in FIG. 2, the method of manufacturing the light-emitting element related to the embodiment of the invention includes a nitride-based compound semiconductor layer forming process S1, an n-type semiconductor layer exposure process S2, a transparent conductive oxide layer forming process S3, a titanium oxide-based conductive film layer forming process S4, an electrode forming process S5, and a photocatalytic reaction prevention layer forming process S6.

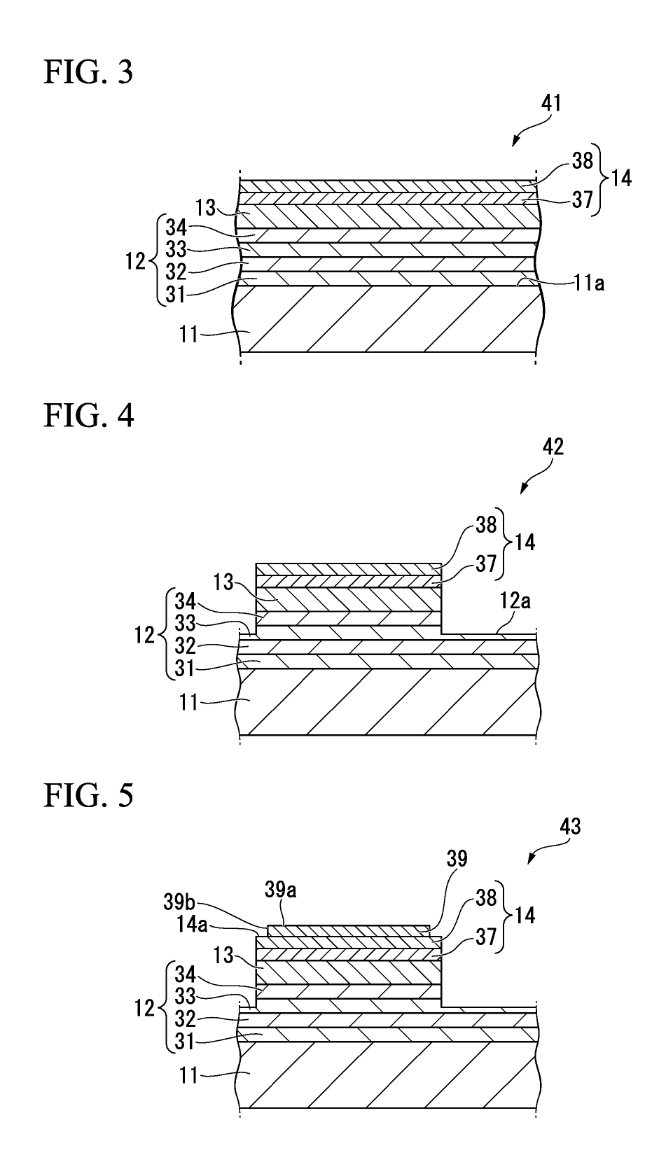

Hereinafter, each process will be described using manufacturing process diagrams shown in FIGS. 3 to 6.

Nitride-based Compound Semiconductor Layer Forming Process S1

The nitride-based compound semiconductor layer forming process S1 is a process of laminating nitride-based compound semiconductors forming the n-type semiconductor layer 12, the light-emitting layer 13, and the p-type semiconductor layer 14, in this order on one face 11a of the substrate 11.

The growth method of the nitride-based compound semiconductor is not particularly limited and all methods of making a nitride semiconductor grow, such as MOCVD (a metal-organic chemical vapor growth method), HVPE (a hydride vapor-phase epitaxial method), and MBE (a molecular beam epitaxy method), can be applied. A preferred growth method is the MOCVD method from the viewpoint of film thickness controllability and mass-productivity.

In the MOCVD method, hydrogen (H₂) or nitrogen (N₂) as carrier gas, trimethylgallium (TMG) or triethylgallium (TEG) as a Ga source that is a III-group raw material, trimethylaluminum (TMA) or triethylaluminum (TEA) as an Al source, trimethylindium (TMI) or triethylindium (TEI) as an In source, ammonia (NH₃) or hydrazine (N₂H₄) as an N source that is a V-group raw material, and the like are used.

Further, as an n-type dopant, monosilane (SiH₄) or disilane (Si₂H₆) can be used as an Si raw material and an organic germanium compound such as germane gas (GeH₄), tetramethylgermanium ((CH₃)₄Ge), or tetraethylgermanium ((C₂H₅)₄Ge) can be used as a Ge raw material.

Further, in the MBE method, elemental germanium can also be used as a doping source.

Further, as a p-type dopant, for example, bis-cyclopentadienyl magnesium (Cp₂Mg) or bis-ethylcyclopentadienyl magnesium (EtCp₂Mg) can be used as an Mg raw material.

In this embodiment, one example using the MOCVD method will be described.

First, the n-type semiconductor layer 12 is formed by laminating a buffer layer 31, a base layer 32, an n-type contact layer 33, and an n-type cladding layer 34 in this order on the one face 11a of the substrate 11 made of sapphire.

It is preferable that the growth temperature when making the base layer 32 grow be set to be in a range of 800° C. to 1200° C., and it is more preferable that it be set in a range of 1000° C. to 1200° C. By performing growth in this temperature range, it is possible to obtain a base layer having excellent crystallinity. Further, it is preferable that pressure in a MOCVD growth furnace be adjusted to be in a range 15 kPa to 40 kPa. Further, it is preferable that the growth temperature of the n-type contact layer 33 be set to be in a range of 800° C. to 1200° C. like the growth temperature of the base layer 32, and it is more preferable that it be set in a range of 1000° C. to 1200° C.

Next, the light-emitting layer 13 having a multiple quantum well structure is formed by laminating an Al_{c}Ga_{1-c}N barrier layer and a GaInN well layer plural times and finally laminating an Al_{c}Ga_{1-c}N barrier layer.

It is preferable that the growth temperature of the Al_{c}Ga_{1-c}N barrier layer be set to be 700° C. or more, and it is more preferable that it be set in a range of 800° C. to 1100° C. By setting the growth temperature of the Al_{c}Ga_{1-c}N barrier layer to be in a range of 800° C. to 1100° C., it is possible to make crystallinity excellent. Further, it is preferable that the growth temperature of the GaInN well layer be set to be 600° C. to 900° C., and it is more preferable that it be set in a range of 700° C. to 900° C. By setting the growth temperature of the GaInN well layer to be in a range of 600° C. to 900° C., it is possible to make crystallinity excellent. That is, in order to make the crystallinity of a MQW structure excellent, it is preferable to change the growth temperature at the time of the formation of the Al_{c}Ga_{1-c}N barrier layer and the growth temperature at the time of the formation of the GaInN well layer.

In addition, as the barrier layer, an Si-doped GaN barrier layer may also be used.

Next, the p-type semiconductor layer 14 is formed by laminating a p-type cladding layer 37 and a p-type contact layer 38.

In this way, a substrate (hereinafter referred to as a first semiconductor substrate) 41 shown in FIG. 3 can be obtained in which the nitride-based compound semiconductor layer composed of the n-type semiconductor layer 12, the light-emitting layer 13, and the p-type semiconductor layer 14 is formed.

N-Type Semiconductor Layer Exposure Process S2

The n-type semiconductor layer exposure process S2 is a process of exposing a portion of the n-type semiconductor layer 12. The exposed area is an area to form the negative electrode and is made by exposing the n-type contact layer 33 by a reactive ion etching method.

First, after resist is evenly applied onto the entire surface of the p-type semiconductor layer 14, the resist is removed from a negative electrode forming area with the use of a known lithography technique.

Next, after setting in a vacuum deposition apparatus, Ni and Ti are laminated under pressure of 4×10⁻⁴ Pa or less by an electron beam method such that film thicknesses respectively become about 50 nm and 300 nm.

Next, a metal film other than the negative electrode forming area is removed along with the resist by a liftoff technique, thereby forming an etching mask.

Next, the first semiconductor substrate 41 is placed on an electrode in an etching chamber of a reactive ion etching apparatus, and after the etching chamber is decompressed to 10⁻⁴ Pa, Cl₂ is supplied as etching gas and etching is performed until the n-type contact layer 33 is exposed. After the etching, the substrate is taken out of the reactive ion etching apparatus and the etching mask is then removed by nitric acid and hydrofluoric acid.

In this way, a substrate (hereinafter referred to as a second semiconductor substrate) 42 shown in FIG. 4, in which a portion of the n-type semiconductor layer 12 is exposed, can be obtained.

Transparent Conductive Oxide Layer Forming Process S3

Next, a target having a first oxide which contains an element that is any one of In, Al, and Ga and a second oxide which contains an element that is either Zn or Sn is mounted at a given position in a vacuum chamber.

Next, the second semiconductor substrate 42 is mounted such that one face 14a of the p-type semiconductor layer 14 faces the target.

Next, by adjusting the film-formation rate and the film-formation time and then performing sputtering on the target, the first oxide which contains an element that is any one of In, Al, and Ga and the second oxide which contains an element that is either Zn or Sn are stuck to one face 14a of the p-type semiconductor layer 14, so that the transparent conductive oxide layer 39 can be formed.

In this way, a substrate (hereinafter referred to as a third semiconductor substrate) 43 shown in FIG. 5, in which the transparent conductive oxide layer 39 is formed, can be obtained.

In addition, in a case where, for example, an ITO, IZO, AZO, or GZO target is used as the above target, it is possible to form the transparent conductive oxide layer 39 composed of at least one or more kinds of materials which are selected from the group consisting of ITO, AZO, IZO, and GZO. Further, it is preferable that the transparent conductive oxide layer 39 be formed only on a positive electrode forming area of the surface of the p-type AlGaN contact layer.

Titanium Oxide-Based Conductive Film Layer Forming Process S4

The titanium oxide-based conductive film layer forming process S4 is a process of forming the titanium oxide-based conductive film layer 15 on the transparent conductive oxide layer 39.

As a method of forming the titanium oxide-based conductive film layer 15, any method such as a vapor deposition method, a sputtering method, a PLD method, or a CVD method can also be used.

In the case of using the vapor deposition method (vacuum deposition method), it is possible to perform film formation with the use of a tablet of Ti₁₋ₓAₓO₂ (A=Ta, Nb, V, Mo, W, or Sb) even by any method such as resistance heating or EB heating. Further, it is also possible to perform film formation by using simple substance metal oxides as separate vapor deposition sources. By using this method, there is an advantage of easier composition control. For example, it is possible to respectively form TiO₂ and Ta₂O₅ by separate vapor deposition sources, thereby making arbitrary Ti₁₋ₓTaₓO₂ composition. Further, it is also possible to perform reactive film-formation with the use of plasma or the like by using simple substance metal or alloy metal and introducing oxygen gas. For example, it is possible to make the Ti₁₋ₓTaₓO₂ composition by evaporating Ti and Ta at separate vapor deposition sources and making Ti and Ta react with oxygen gas by plasma. Further, in order to improve adhesiveness or intricacy, substrate heating or ion assistance may also be used.

In addition, in the vapor deposition method, since the energy of a particle at the time of vapor deposition is not so large, a film made of a titanium oxide-based conductive film which is obtained becomes a film in which an amorphous state or crystallinity corresponding thereto is low. However, by setting the substrate temperature during vapor deposition to be in a range of 300° C. to 800° C. or performing a thermal treatment at a temperature in a range of 300° C. to 800° C. after film formation, it is possible to form a film which is dense and has high crystallinity. In a case where the temperature of the thermal treatment is set to be less than 300° C., the effect of improving crystallization is small, so that it is not possible to form a film which is dense and has high crystallinity. In contrast, in a case where the temperature of the thermal treatment is set to exceed 800° C., the nitride-based compound semiconductor is damaged.

In the case of using the sputtering method, it is possible to perform film formation with the use of a target of Ti₁₋ₓAₓO₂ (A=Ta, Nb, V, Mo, W, or Sb) even by using any method such as RF or DC. Further, it is also possible to perform film formation by using the respective simple substance metal oxides as separate targets. By using a method of forming a film with the simple substance metal oxides as separate targets, easier composition control is possible. For example, it is possible to perform the film-formation of TiO₂ and Ta₂O₅ by separate targets, thereby making Ti₁₋ₓTaₓO₂ of arbitrary composition. Further, it is also possible to perform reactive sputtering film-formation by using simple substance metal or alloy metal and introducing oxygen gas. For example, it is possible to make the Ti₁₋ₓTaₓO₂ composition by electrically discharging Ti and Ta at separate targets and making Ti and Ta react with oxygen gas in plasma. Further, in order to improve adhesiveness or intricacy, substrate heating or bias may also be used.

In addition, in the sputtering method, the energy of a sputter particle at the time of sputtering is large, so that it is possible to obtain the titanium oxide-based conductive film layer 15 which is dense and has high crystallinity. By forming the titanium oxide-based conductive film layer 15 as a film which is dense and has high crystallinity, it is possible to make it difficult for the titanium oxide-based conductive film layer 15 to be eroded at the time of etching.

In this embodiment, the titanium oxide-based conductive film layer 15 made of Ti_{0.95}Nb_{0.05}O₂ is formed by using a known photolithography technique, a liftoff technique, a sputtering method or a vapor deposition method.

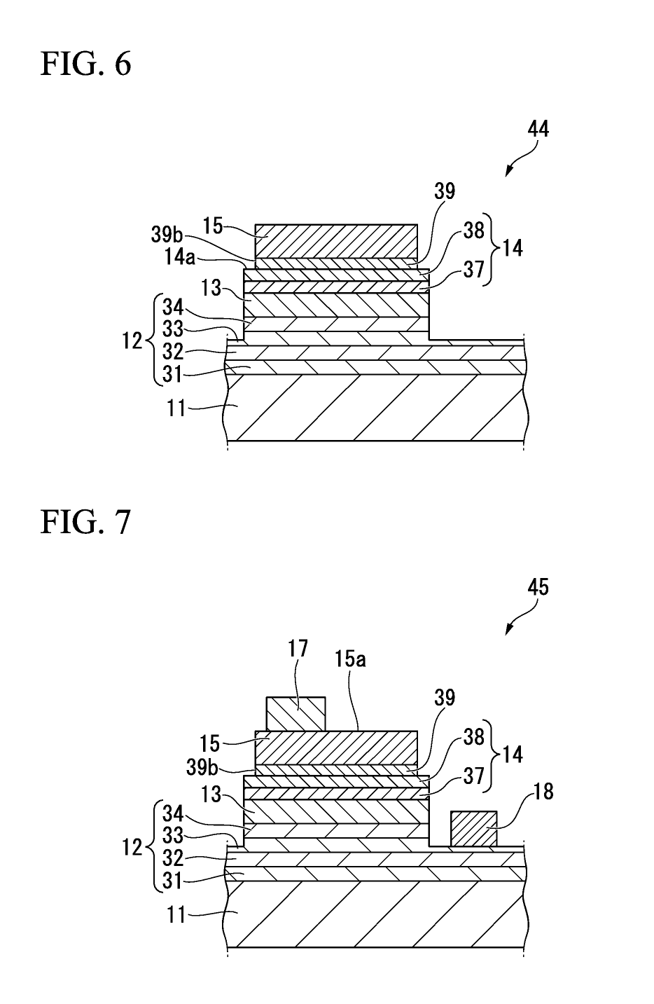

In this way, a substrate (hereinafter referred to as a fourth semiconductor substrate) 44 shown in FIG. 6, in which the titanium oxide-based conductive film layer 15 is formed, can be obtained.

Thereafter, an annealing treatment is performed at a treatment temperature of 350° C., for example. In this way, even in a case where the film thickness of the transparent conductive oxide layer 39 is thin, so that it is not formed as a layer, it is possible to diffuse constituent elements of the first oxide which contains an element that is any of In, Al, and Ga and the second oxide which contains an element that is either Zn or Sn, which are stuck to one face 14a of the p-type semiconductor layer 14, between the p-type semiconductor layer 14 and the titanium oxide-based conductive film layer 15.

Electrode Forming Process S5

The electrode forming process S5 is a process of forming the positive electrode 17 on one face 15a of the titanium oxide-based conductive film layer 15 and forming the negative electrode 18 on the exposed face 12a of the n-type semiconductor layer 12.

First, the positive electrode 17 and the negative electrode 18, each having a five-layer structure, are formed by sequentially laminating a first layer made of Au, a second layer made of Ti, a third layer made of Al, a fourth layer made of Ti, and a fifth layer made of Au on one face 15a of the titanium oxide-based conductive film layer 15 and the exposed face 12a of the n-type semiconductor layer 12 with the use of a well-known procedure called liftoff and a well-known lamination method.

In this way, a substrate (hereinafter referred to as a fifth semiconductor substrate) 45 shown in FIG. 7, in which the electrodes are formed, can be obtained.

Photocatalytic Reaction Prevention Layer Forming Process S6 (Protective Film Layer Forming Process S6)

The photocatalytic reaction prevention layer forming process S6 is a process of forming the photocatalytic reaction prevention layer 16 so as to cover the titanium oxide-based conductive film layer 15.

In the film formation of the photocatalytic reaction prevention layer 16, a film formation method capable of forming a dense film, such as a sputtering method or a CVD method, can be used. Especially, it is preferable to use the CVD method because a more dense film can be formed.

In the case of performing the film formation of SiO₂ by the CVD method, TEOS (tetraethoxysilane), TMS (trimethoxysilane), SiH₄, or the like can be used as a raw material.

Further, In the case of performing the film formation of Al₂O₃ by the CVD method, TMA (trimethylaluminum), DMA (dimethylaluminum), an alkoxy compound (isopropoxy dimethylaluminum, sec-butoxy dimethylaluminum, isopropoxy diethylaluminum, or tert-butoxy dimethylaluminum), or the like can be used as a raw material.

In addition, a method using a liquid application material such as SOG (spin-on-glass) which is used to make SiO₂ is not preferable as the method of forming the photocatalytic reaction prevention layer 16 because a dense film is not easily made. Further, in a film which is made by this method, even if annealing is performed, moisture remains in the film, so that the film is not suitable for the photocatalytic reaction prevention layer 16.

In this embodiment, the photocatalytic reaction prevention layer 16 made of Al₂O₃ is formed on areas other than the central portion of the positive electrode 17 and the negative electrode 18 by a CVD method with the use of a known photolithography technique and liftoff technique. In this way, a substrate (hereinafter referred to as a sixth semiconductor substrate) in which the photocatalytic reaction prevention layer 16 is formed can be obtained.

Thereafter, by dividing (chipping) the sixth semiconductor substrate, it is possible to obtain the light-emitting element 1 shown in FIG. 1.

Lamp

Next, a lamp (LED lamp) related to an embodiment of the invention will be described.

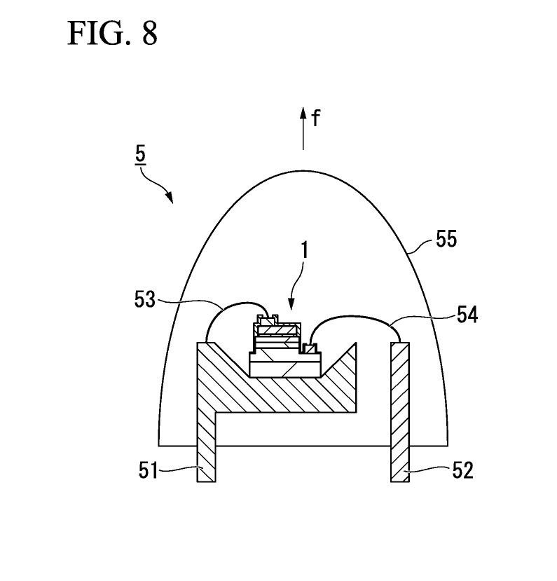

FIG. 8 is a cross-sectional schematic view illustrating one example of the lamp related to the embodiment of the invention.

As shown in FIG. 8, a lamp 5 related to the embodiment of the invention is schematically constituted by bonding the face-up type light-emitting element 1 composed of nitride-based compound semiconductors shown in FIG. 1 to frames 51 and 52 by wires 53 and 54 and then packaging it into the form of a bullet by a mold 55.

The lamp (LED lamp) 5 related to the embodiment of the invention can be manufactured by a known conventional method with the use of the light-emitting element 1 related to the embodiment of the invention.

Specifically, for example, the light-emitting element 1 is adhered to one (in FIG. 8, the frame 51) of two frames 51 and 52 by resin or the like, the positive electrode 17 and the negative electrode 18 of the light-emitting element 1 are respectively bonded to the frames 51 and 52 by wires 53 and 54 made of a material such as gold, and thereafter, the periphery of the light-emitting element 1 is molded by the mold 55 made of transparent resin, whereby a lamp in the form of a bullet shown in FIG. 8 can be manufactured.

In addition, the lamp 5 is not limited to the above-described configuration. For example, a phosphor may also be dispersed in the mold 55 or the light-emitting element 1 and a cover having a phosphor may also be combined. It is possible to configure a white light lamp by mixing the luminescent color of the light-emitting element 1 and the luminescent color of the phosphor.

Further, the lamp 5 can also be used for any use such as a bullet type for a general use, a side-view type for portable backlight use, or a top-view type which is used in a display instrument.

Since the light-emitting element 1 related to the embodiment of the invention is configured to include the n-type semiconductor layer 12, the light emission layer 13, the p-type semiconductor layer 14, and the titanium oxide-based conductive film layer 15, which are laminated in this order on one face 11a of the substrate 11, wherein the first oxide which contains an element that is any of In, Al, and Ga and the second oxide which contains an element that is either Zn or Sn are present between the p-type semiconductor layer 14 and the titanium oxide-based conductive film layer 15, and the mass ratio of the second oxide to the total of the first oxide and the second oxide is in a range of 1 mass % to 20 mass %, it is possible to provide a light-emitting element in which the conductivity between the p-type semiconductor layer 14 and the titanium oxide-based conductive film layer 15 is improved, so that the driving voltage Vf of the light-emitting element is reduced, and also the total reflection of light does not occur between the p-type semiconductor layer 14 and the titanium oxide-based conductive film layer 15, so that light extraction efficiency is improved.

Since the light-emitting element 1 related to the embodiment of the invention has a configuration in which the transparent conductive oxide layer 39 which includes the first oxide and the second oxide is formed between the p-type semiconductor layer 14 and the titanium oxide-based conductive film layer 15, it is possible to provide a light-emitting element in which the driving voltage is reduced and light extraction efficiency is improved.

Since the light-emitting element 1 related to the embodiment of the invention has a configuration in which the film thickness of the transparent conductive oxide layer 39 is 10 nm or less, it is possible to provide a light-emitting element in which the driving voltage is reduced and light extraction efficiency is improved.

Since the light-emitting element 1 related to the embodiment of the invention has a configuration in which the transparent conductive oxide layer 39 is composed of at least one or more kinds of materials which are selected from the group consisting of ITO, AZO, IZO, and GZO, it is possible to provide a light-emitting element in which the driving voltage is reduced and light extraction efficiency is improved.

Since the light-emitting element 1 related to the embodiment of the invention has a configuration in which the titanium oxide-based conductive film layer 15 is made of a Ti oxide which contains at least one or more kinds of elements which are selected from the group consisting of Ta, Nb, V, Mo, W, and Sb, it is possible to provide a light-emitting element in which the driving voltage is reduced and light extraction efficiency is improved.

Since the light-emitting element 1 related to the embodiment of the invention has a configuration in which the film thickness of the titanium oxide-based conductive film layer 15 is in a range of 35 nm to 2000 nm, it is possible to provide a light-emitting element in which the driving voltage is reduced and light extraction efficiency is improved.

Since the light-emitting element 1 related to the embodiment of the invention has a configuration in which the titanium oxide-based conductive film layer 15 is composed of granular crystals, it is possible to provide a light-emitting element in which the driving voltage is reduced and light extraction efficiency is improved.

Since the light-emitting element 1 related to the embodiment of the invention has a configuration in which the n-type semiconductor layer 12, the light-emitting layer 13, and the p-type semiconductor layer 14 are composed of nitride-based compound semiconductors, it is possible to provide a light-emitting element in which the driving voltage is reduced and light extraction efficiency is improved.

Since the light-emitting element 1 related to the embodiment of the invention has a configuration in which the nitride-based compound semiconductor is a GaN-based compound semiconductor, it is possible to provide a light-emitting element in which the driving voltage is reduced and light extraction efficiency is improved.

Since the method of manufacturing the light-emitting element 1 related to the embodiment of the invention is configured to include a process of laminating the n-type semiconductor layer 12, the light-emitting layer 13, and the p-type semiconductor layer 14 in this order on one face 11a of the substrate 11 and then forming the transparent conductive oxide layer 39 which includes the first oxide which contains an element that is any one of In, Al, and Ga and the second oxide which contains an element that is either Zn or Sn on the surface 14a of the p-type semiconductor layer 14 by a sputtering method and a process of forming the titanium oxide-based conductive film layer 15 on the transparent conductive oxide layer 39, it is possible to manufacture a light-emitting element in which the first oxide which contains an element that is any of In, Al, and Ga and the second oxide which contains an element that is either Zn or Sn are present between the p-type semiconductor layer 14 and the titanium oxide-based conductive film layer 15, whereby the conductivity between the p-type semiconductor layer 14 and the titanium oxide-based conductive film layer 15 is improved, so that the driving voltage Vf of the light-emitting element can be reduced, and also the total reflection of light does not occur between the p-type semiconductor layer 14 and the titanium oxide-based conductive film layer 15, so that light extraction efficiency is improved.

Since the method of manufacturing the light-emitting element 1 related to the embodiment of the invention has a configuration in which an annealing treatment is performed after the titanium oxide-based conductive film layer 15 is formed, it is possible to manufacture a light-emitting element in which the element that is any one of In, Al, and Ga in the first oxide and the element that is either Zn or Sn in the second oxide are evenly dispersed between the p-type semiconductor layer 14 and the titanium oxide-based conductive film layer 15, so that driving voltage is reduced and light extraction efficiency is improved.

Since the lamp 5 related to the embodiment of the invention is configured to be provided with the light-emitting element 1, it is possible to make a lamp in which the conductivity between the p-type semiconductor layer 14 and the titanium oxide-based conductive film layer 15 is improved, so that the driving voltage Vf of the light-emitting element is reduced, and also the total reflection of light does not occur between the p-type semiconductor layer 14 and the titanium oxide-based conductive film layer 15, so that light extraction efficiency is improved.

Further, since the lamp 5 manufactured from the semiconductor light-emitting element according to the invention has the excellent effects as described above, electronic equipment such as a backlight, a mobile telephone, a display, various panels, a computer, a game machine, and lighting, in which the lamp 5 manufactured by this technique is incorporated therein, or machinery such as an automobile, in which the electronic equipment is incorporated therein, has high reliability as a product in use. Especially, battery-driven equipment such as a backlight, a mobile telephone, a display, a game machine, and lighting, which has a light-emitting element having excellent corrosion resistance and high reliability, can be provided, which is preferable.

### Second Embodiment

A light-emitting element related to a second embodiment of the invention will be described.

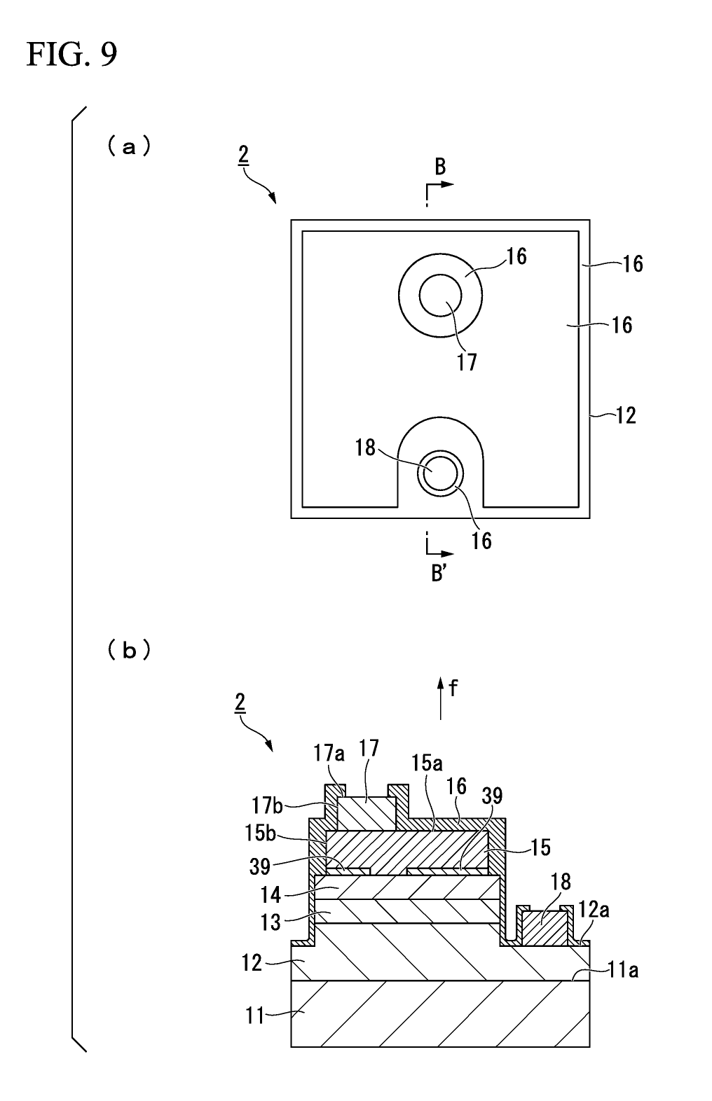

FIG. 9 is a diagram illustrating one example of a light-emitting element 2 related to the embodiment of the invention, wherein FIG. 9(a) is a plan view and FIG. 9(b) is a cross-sectional view taken along line B-B′ in FIG. 9(a). In addition, the same member as the member shown in Embodiment 1 is shown being denoted by the same symbol.

As shown in FIG. 9(b), the light-emitting element 2 related to the embodiment of the invention has the same configuration as the light-emitting element 1 shown in the first embodiment with the exception that the transparent conductive oxide layer 39 is formed to be thin in film thickness between the p-type semiconductor layer 14 and the titanium oxide-based conductive film layer 15.

As shown in FIG. 9(b), in this embodiment, the transparent conductive oxide layer 39 is formed to be thin in film thickness and the first oxide which contains an element that is any one of In, Al, and Ga and the second oxide which contains an element that is either Zn or Sn are present between the p-type semiconductor layer 14 and the titanium oxide-based conductive film layer 15. Further, the first oxide and the second oxide partially cover the p-type semiconductor layer. Furthermore, the mass ratio of the second oxide to the total of the first oxide and the second oxide is made to be in a range of 1 mass % to 20 mass %. By taking such a structure, the conductivity between the p-type semiconductor layer 14 and the titanium oxide-based conductive film layer 15 can be improved, so that the driving voltage Vf of the light-emitting element can be reduced. Further, it is possible to secure a transmittance of 80% or more in a wavelength in a range of 300 nm to 550 nm, so that it is possible to improve light extraction efficiency in the front direction f.

The light-emitting element 2 related to the embodiment of the invention can be manufactured by using the same manufacturing process as the manufacturing process shown in the first embodiment with the exception that sputtering conditions are changed in the transparent conductive oxide layer forming process S3.

For example, by shortening a sputtering time or making sputtering energy small when performing sputtering by using an ITO, IZO, AZO, or GZO target, the film thickness of the transparent conductive oxide layer 39 can be thinly made between the p-type semiconductor layer 14 and the titanium oxide-based conductive film layer 15 and the first oxide and the second oxide can be formed between the p-type semiconductor layer 14 and the titanium oxide-based conductive film layer 15 so as to partially cover the p-type semiconductor layer.

Since the light-emitting element 2 related to the embodiment of the invention is configured to include the n-type semiconductor layer 12, the light emission layer 13, the p-type semiconductor layer 14, and the titanium oxide-based conductive film layer 15, which are laminated in this order on one face 11a of the substrate 11, wherein the first oxide which contains an element that is any of In, Al, and Ga and the second oxide which contains an element that is either Zn or Sn are present between the p-type semiconductor layer 14 and the titanium oxide-based conductive film layer 15, and the mass ratio of the second oxide to the total of the first oxide and the second oxide is in a range of 1 mass % to 20 mass %, it is possible to provide a light-emitting element in which the conductivity between the p-type semiconductor layer 14 and the titanium oxide-based conductive film layer 15 is improved, so that the driving voltage Vf of the light-emitting element is reduced, and also the total reflection of light does not occur between the p-type semiconductor layer 14 and the titanium oxide-based conductive film layer 15, so that light extraction efficiency is improved.

Since the light-emitting element 2 related to the embodiment of the invention has a configuration in which the first oxide and the second oxide at least partially cover the p-type semiconductor layer 14, it is possible to manufacture a light-emitting element in which the driving voltage is reduced and light extraction efficiency is improved.

Since a method of manufacturing the light-emitting element 2 related to the embodiment of the invention has a configuration in which in the transparent conductive oxide layer forming process, the film thickness of the transparent conductive oxide layer is thinly formed such that the first oxide and the second oxide at least partially cover the p-type semiconductor layer 14, it is possible to manufacture a light-emitting element in which the driving voltage is reduced and light extraction efficiency is improved.

Since the method of manufacturing the light-emitting element 2 related to the embodiment of the invention has a configuration in which an annealing treatment is performed after the titanium oxide-based conductive film layer 15 is formed, it is possible to uniformly disperse the first oxide and the second oxide between the p-type semiconductor layer 14 and the titanium oxide-based conductive film layer 15.

### EXAMPLE

Hereinafter, the invention will be specifically described on the basis of examples. However, the invention is not limited to these examples only.

### Example 1

### Manufacturing of Gallium Nitride-Based Compound Semiconductor Light-Emitting Element

The gallium nitride-based compound semiconductor light-emitting element shown in FIG. 1 or 9 was manufactured according to the flow chart shown in FIG. 2 and the manufacturing process diagrams shown in FIGS. 3 to 7.

First, a buffer layer made of AlN was formed on one face of a sapphire substrate which becomes a substrate for a plurality of light-emitting elements, by an MOCVD method.

Next, an n-type semiconductor layer was formed by laminating a base layer made of undoped GaN and having a thickness of 8 μm, an Si-doped n-type GaN contact layer having a thickness of 2 μm, and an n-type In_{0.1}Ga_{0.9}N cladding layer having a thickness of 0.02 μm on this order. The carrier concentration of the n-type GaN contact layer was set to be 1×10¹⁹ cm⁻³.

Next, a light-emitting layer having a multiple quantum well structure was formed by laminating an Si-doped GaN barrier layer having a thickness of 16 nm and an In_{0.06}Ga_{0.94}N well layer having a thickness of 2.5 nm five times and finally providing a barrier layer. The Si doping amount of the GaN barrier layer was set to be 1×10¹⁷ cm⁻³.

Next, a p-type semiconductor layer was formed by laminating an Mg-doped p-type Al_{0.07}Ga_{0.93}N cladding layer having a thickness of 0.01 μm and an Mg-doped p-type Al_{0.02}Ga_{0.98}N contact layer having a thickness of 0.18 μm in this order. The carrier concentration of the p-type AlGaN contact layer was set to be 5×10¹⁸ cm⁻³ and the Mg doping amount of the p-type AlGaN cladding layer was set to be 5×10¹⁹ cm⁻³.

In addition, the lamination of the gallium nitride-based compound semiconductor layers was performed under normal conditions well known in the art, by the MOCVD method.

Next, after resist is evenly applied onto the entire surface of the p-type semiconductor layer, the resist was removed from a negative electrode forming area with the use of a known lithography technique.

Next, it was set in a vacuum deposition apparatus and Ni and Ti were laminated under pressure of 4×10⁻⁴ Pa or less by an electron beam method such that film thicknesses respectively become about 50 nm and 300 nm.

Next, a metal film other than the negative electrode forming area was removed along with the resist by a liftoff technique.

Next, after the semiconductor laminated substrate is placed on an electrode in an etching chamber of a reactive ion etching apparatus and the etching chamber is then decompressed to 10⁻⁴ Pa, etching was performed by supplying Cl₂ as etching gas until the n-type GaN contact layer was exposed. After the etching, the substrate was taken out of the reactive ion etching apparatus and the etching mask was removed by nitric acid and hydrofluoric acid.

Next, the semiconductor substrate was set in the inside of a vacuum chamber such that one face of the p-type semiconductor layer faced an IZO target.

Next, by performing sputtering with the use of the IZO target, IZO was formed in a positive electrode forming area on the surface of the p-type AlGaN contact layer, which is one face of the p-type semiconductor layer. At this time, the film thickness of a transparent conductive oxide layer made of IZO having a first oxide which contains In and a second oxide which contains Zn was 5 nm.

Next, a titanium oxide-based conductive film layer made of Ti_{0.95}Nb_{0.05}O₂ was formed in a film thickness of 200 nm on the transparent conductive oxide layer by using a known photolithography technique, a liftoff technique, and a sputtering method.

Thereafter, an annealing treatment was performed at a treatment temperature of 350° C.

Next, a positive electrode having a five-layer structure was formed by laminating a first layer made of Au, a second layer made of Ti, a third layer made of Al, a fourth layer made of Ti, and a fifth layer made of Au on a portion of the titanium oxide-based conductive film layer in order with the use of a well-known procedure called liftoff and a well-known lamination method. Here, the thicknesses of the respective layers made of Au, Ti, Al, Ti, and Au were respectively set to be 50, 20, 10, 100, and 500 nm.

Next, after resist is evenly applied onto the entire surface of an exposed area of the n-type GaN contact layer, the resist was removed from a negative electrode forming portion on the exposed n-type GaN contact layer by using a known lithography technique.

Next, a negative electrode was formed by forming a Ti film having a thickness of 100 nm and an Au film having a thickness of 200 nm in order from the semiconductor side by a vacuum deposition method.

Next, the resist was removed by a known method.

Next, a photocatalytic reaction prevention layer made of Al₂O₃ was formed in a thickness of 500 nm on areas other than the central portions of the positive electrode and the negative electrode by a CVD method with the use of a known photolithography technique and a liftoff technique.

Next, a wafer in which the formation of up to the photocatalytic reaction prevention layer was completed was cut into chips (the light-emitting elements of Example 1) of 350 μm square by thinning the thickness of the substrate up to 80 μm by grinding and polishing of the back surface of the substrate, scribing a marking line from the semiconductor lamination side by using a laser scriber, and then press-dividing it.

Element Characteristic Evaluation

With respect to the chip (the light-emitting element of Example 1), driving voltage Vf (V) was examined by performing energization by a probe needle and measuring forward voltage in an applied electric current of 20 mA.

Further, the obtained chip was mounted in a TO-18 can package and a luminescence output (mW) in an applied electric current of 20 mA was then measured by a tester.

### Example 2

A light-emitting element of Example 2 was manufactured in the same way as in Example 1 with the exception that a transparent conductive oxide layer made of IZO was formed in a film thickness of 0.5 nm in the transparent conductive oxide layer forming process. Thereafter, the evaluation of element characteristics was performed similarly to Example 1.

### Example 3

A light-emitting element of Example 3 was manufactured in the same way as in Example 1 with the exception that a transparent conductive oxide layer made of IZO was formed in a film thickness of 2 nm in the transparent conductive oxide layer forming process. Thereafter, the evaluation of element characteristics was performed similarly to Example 1.

### Example 4

A light-emitting element of Example 4 was manufactured in the same way as in Example 1 with the exception that a transparent conductive oxide layer made of IZO was formed in a film thickness of 10 nm in the transparent conductive oxide layer forming process. Thereafter, the evaluation of element characteristics was performed similarly to Example 1.

### Example 5

A light-emitting element of Example 5 was manufactured in the same way as in Example 1 with the exception that a transparent conductive oxide layer made of ITO was formed in a film thickness of 5 nm in the transparent conductive oxide layer forming process. Thereafter, the evaluation of element characteristics was performed similarly to Example 1.

### Example 6

A light-emitting element of Example 6 was manufactured in the same way as in Example 1 with the exception that a transparent conductive oxide layer made of AZO was formed in a film thickness of 5 nm in the transparent conductive oxide layer forming process. Thereafter, the evaluation of element characteristics was performed similarly to Example 1.

### Example 7

A light-emitting element of Example 7 was manufactured in the same way as in Example 1 with the exception that a transparent conductive oxide layer made of GZO was formed in a film thickness of 5 nm in the transparent conductive oxide layer forming process. Thereafter, the evaluation of element characteristics was performed similarly to Example 1.

### Comparative Example 1

A light-emitting element of Comparative example 1 was manufactured in the same way as in Example 1 with the exception that the mass of the second oxide which contains Zn was set to be 30 mass % with respect to the total mass of the first oxide which contains In and the second oxide which contains Zn in the transparent conductive oxide layer forming process. Thereafter, the evaluation of element characteristics was performed similarly to Example 1.

### Comparative Example 2

A light-emitting element of Comparative example 2 was manufactured in the same way as in Example 1 with the exception that the mass of the second oxide which contains Zn was set to be 0.1 mass % with respect to the total mass of the first oxide which contains In and the second oxide which contains Zn in the transparent conductive oxide layer forming process. Thereafter, the evaluation of element characteristics was performed similarly to Example 1.

### Comparative Example 3

A light-emitting element of Comparative example 3 was manufactured in the same way as in Example 1 with the exception that a transparent conductive oxide layer made of IZO was formed in a film thickness of 20 nm in the transparent conductive oxide layer forming process. Thereafter, the evaluation of element characteristics was performed similarly to Example 1.

### Comparative Example 4

A light-emitting element of Comparative example 4 was manufactured in the same way as in Example 1 with the exception that after a titanium oxide-based conductive film layer was formed on the face on the opposite side to the substrate of the p-type semiconductor layer without forming a first oxide which contains In and a second oxide which contains Zn, a transparent conductive oxide layer made of IZO was formed in a film thickness of 0.5 nm on one face (the face on the opposite side to the substrate) of the titanium oxide-based conductive film layer. This element structure is a structure in which the laminating sequence of the titanium oxide-based conductive film layer and the transparent conductive oxide layer is reversed in the element structure shown in Example 2. Thereafter, the evaluation of element characteristics was performed similarly to Example 1.

In Table 1, the element structures of Examples 1 to 7 and Comparative examples 1 to 4, the conditions of the transparent conductive oxide layer, the concentration of In, Al, Ga, Zn, and Sn between the p-type semiconductor layer and the titanium oxide-based conductive film layer, and the results of the light-emitting element characteristics are shown. In addition, a case where the driving voltage Vf is 3.3 V or less and the luminescence output is 18 mW or more was evaluated as “A” and the others were evaluated as “B”.

TABLE 1

| | | | | | | | | | Ratio of | | | |
|---|---|---|---|---|---|---|---|---|---|---|---|---|
| | | | | | | | | | the second | | | |
| | | | | | | | | | oxide in | | | |
| | Transparent conductive | | | | | | | | trans- | Light-emitting element | | |
| | oxide layer | | | | | | | | parent | characteristics | | |
| | | | Film | | | | | | conductive | Driving | Lumi- | |
| | | | thick- | | | | Second oxide | | oxide | voltage | nescence | |
| | | Refractive | ness | First oxide element | | | element | | layer | Vf | output | |
| | Kind | index | (nm) | In | Al | Ga | Zn | Sn | (mass %) | (V) | (mW) | Evaluation |
| Example 1 | IZO | 1.9 | 5 | presence | — | — | presence | — | 10 | 3.2 | 20 | A |
| Example 2 | IZO | 1.9 | 0.5 | presence | — | — | presence | — | 10 | 3.3 | 20 | A |
| Example 3 | IZO | 1.9 | 2 | presence | — | — | presence | — | 10 | 3.3 | 20 | A |
| Example 4 | IZO | 1.9 | 10 | presence | — | — | presence | — | 10 | 3.2 | 20 | A |
| Example 5 | ITO | 1.9 | 5 | presence | — | — | — | presence | 10 | 3.2 | 19 | A |
| Example 6 | AZO | 2.1 | 5 | — | presence | — | presence | — | 10 | 3.2 | 20 | A |
| Example 7 | GZO | 2.1 | 5 | — | — | presence | presence | — | 10 | 3.3 | 18 | A |
| Comparative | IZO | 1.9 | 5 | presence | — | — | presence | — | 30 | 3.2 | 17 | B |
| example 1 | | | | | | | | | | | | |
| Comparative | IZO | 1.9 | 5 | presence | — | — | presence | — | 0.1 | 3.4 | 19 | B |
| example 2 | | | | | | | | | | | | |
| Comparative | IZO | 1.9 | 20 | presence | — | — | presence | — | 10 | 3.2 | 17 | B |
| example 3 | | | | | | | | | | | | |
| Comparative | IZO | 1.9 | 0.5 | presence | — | — | presence | — | 10 | 3.4 | 17 | B |
| example 4 | | | | | | | | | | | | |

The structure of Comparative example 4 is a structure in which the laminating sequence of the titanium oxide-based conductive film layer and the transparent conductive film layer is reversed in the structure shown in Example 2.

### INDUSTRIAL APPLICABILITY

The invention relates to a light-emitting element in which the driving voltage is reduced and light extraction efficiency is improved, a method of manufacturing the light-emitting element, a lamp, electronic equipment, and a mechanical apparatus, and can be used in an industry of manufacturing and using a light-emitting element in which the driving voltage is reduced and light extraction efficiency is improved.

### REFERENCE SIGNS LIST

1, 2: light-emitting element
5: lamp
11: substrate
11a: one face
12: n-type semiconductor layer
12a: one face (face on the opposite side to substrate)
13: light-emitting layer
14: p-type semiconductor layer
14a: one face (face on the opposite side to substrate: surface)
15: titanium oxide-based conductive film layer
15a: one face (face on the opposite side to substrate)
15b: side surface
16: photocatalytic reaction prevention layer (protective film layer)
17: positive electrode
17a: upper surface peripheral portion
17b: side surface
18: negative electrode
31: buffer layer
32: base layer
33: n-type contact layer
34: n-type cladding layer
37: p-type cladding layer
38: p-type contact layer
39: transparent conductive oxide layer
41: first semiconductor substrate
42: second semiconductor substrate
43: third semiconductor substrate
44: fourth semiconductor substrate
45: fifth semiconductor substrate
51, 52: frame
53, 54: wire
55: mold

1. A light-emitting element comprising:
an n-type semiconductor layer;
a light-emitting layer;
a p-type semiconductor layer; and
a titanium oxide-based conductive film layer, which are laminated in this order on one face of a substrate,
wherein a first oxide which contains an element that is any one selected from the group consisting of In, Al, and Ga and a second oxide which contains an element that is either Zn or Sn are present between the p-type semiconductor layer and the titanium oxide-based conductive film layer, and the mass ratio of the second oxide to the total of the first oxide and the second oxide is in a range of 1 mass % to 20 mass %.

2. The light-emitting element according to claim 1, wherein the first oxide and the second oxide at least partially cover the p-type semiconductor layer.

3. The light-emitting element according to claim 1, wherein a transparent conductive oxide layer which includes the first oxide and the second oxide is formed between the p-type semiconductor layer and the titanium oxide-based conductive film layer.

4. The light-emitting element according to claim 3, wherein the film thickness of the transparent conductive oxide layer is 10 nm or less.

5. The light-emitting element according to claim 3, wherein the transparent conductive oxide layer is composed of at least one or more kinds of materials which are selected from the group consisting of ITO, AZO, IZO, and GZO.

6. The light-emitting element according to claim 1, wherein the titanium oxide-based conductive film layer is made of a Ti oxide which contains at least one or more kinds of elements which are selected from the group consisting of Ta, Nb, V, Mo, W, and Sb.

7. The light-emitting element according to claim 1, wherein the film thickness of the titanium oxide-based conductive film layer is in a range of 35 nm to 2000 nm.

8. The light-emitting element according to claim 1, wherein the titanium oxide-based conductive film layer is composed of granular crystals.

9. The light-emitting element according to claim 1, wherein the n-type semiconductor layer, the light-emitting layer, and the p-type semiconductor layer are composed of nitride-based compound semiconductors.

10. The light-emitting element according to claim 9, wherein the nitride-based compound semiconductor is a GaN-based compound semiconductor.

11. A method of manufacturing a light-emitting element comprising:
a process of laminating an n-type semiconductor layer, a light-emitting layer, and a p-type semiconductor layer in this order on one face of a substrate and then forming a transparent conductive oxide layer which includes a first oxide which contains an element that is any one selected from the group consisting of In, Al, and Ga and a second oxide which contains an element that is either Zn or Sn on the surface of the p-type semiconductor layer by a sputtering method; and
a process of forming a titanium oxide-based conductive film layer on the transparent conductive oxide layer.

12. The method of manufacturing a light-emitting element according to claim 11, wherein in the transparent conductive oxide layer forming process, the transparent conductive oxide layer is formed such that the first oxide and the second oxide at least partially cover the p-type semiconductor layer.

13. The method of manufacturing a light-emitting element according to claim 11, wherein an annealing treatment is performed after the titanium oxide-based conductive film layer is formed.

14. A lamp comprising the light-emitting element according to claim 1.

15. Electronic equipment comprising the lamp according to claim 14.

16. A mechanical apparatus comprising the electronic equipment according to claim 15.
